(19) United States
(12) Patent Application Publication
(10) Pub. No.: US 2016/0276497 A1
(43) Pub. Date: Sep. 22, 2016

(54) SEMICONDUCTOR DEVICE AND MANUFACTURING METHOD THEREOF

(71) Applicant: KABUSHIKI KAISHA TOSHIBA, Tokyo (JP)

(72) Inventor: Makoto MIZUKAMI, Ibo Hyogo (JP)

(21) Appl. No.: 14/840,814

(22) Filed: Aug. 31, 2015

(30) Foreign Application Priority Data
Mar. 16, 2015 (JP) 2015-052277

(51) Int. Cl. H01L 29/868; H01L 29/16; H01L 21/04; H01L 29/66

(52) U.S. Cl. CPC H01L 29/868; H01L 29/6606; H01L 29/1608; H01L 21/046; H01L 21/0485

(57) ABSTRACT

A semiconductor device includes a SiC substrate having first and second surfaces, p-type first SiC areas on the first surface of the SiC substrate, an n-type second SiC area between the first SiC areas and the second surface, a third SiC area having an n-type dopant concentration higher than that of the second SiC area, on the second surface of the SiC substrate, a first electrode on the first surface and electrically connected to the first SiC areas, and a second electrode on the second surface and electrically connected to the third SiC area. Where the area between the first SiC areas and the second surface is a first area, and the area between a portion between adjacent first SiC areas and the second surface is set as a second area, a Z_{1/2} level density of the first area is higher than that of the second area.

### CROSS-REFERENCE TO RELATED APPLICATION

This application is based upon and claims the benefit of priority from Japanese Patent Application No. 2015-052277, filed Mar. 16, 2015, the entire contents of which are incorporated herein by reference.

### FIELD

Exemplary embodiments described herein relate to a semiconductor device and a manufacturing method thereof.

### BACKGROUND

In a bipolar device such as a PIN diode, it is desirable to reduce switching losses. For example, when the lifetime of minority carriers is increased, the conductivity modulation effect is improved, and the on-resistance of the device is reduced. However, if the lifetime of minority carriers is increased, the time (reverse recovery time) required to discharge the minority carriers when the diode is turned off is increased, so that switching losses increase. In addition, for example, if the quantity of injected minority carriers is increased, the conductivity modulation effect is improved, and the on-resistance is reduced. However, if the quantity of injected minority carriers is increased, the time (reverse recovery time) required to discharge the minority carriers when the diode is turned off is increased, and switching losses are increased.

### DESCRIPTION OF THE DRAWINGS

FIG. 1 is a sectional view schematically illustrating a semiconductor device according to a first exemplary embodiment.

FIG. 2 is a diagram illustrating functions and effects of the semiconductor device according to the first exemplary embodiment.

FIG. 3 is a sectional view schematically illustrating a semiconductor device in the middle of a manufacturing method of the semiconductor device according to a second exemplary embodiment.

FIG. 4 is a sectional view schematically illustrating the semiconductor device in the middle of the manufacturing method of the semiconductor device according to the second exemplary embodiment.

FIG. 5 is a sectional view schematically illustrating the semiconductor device in the middle of the manufacturing method of the semiconductor device according to the second exemplary embodiment.

FIG. 6 is a sectional view schematically illustrating a semiconductor device in the middle of a manufacturing method of the semiconductor device according to a third exemplary embodiment.

FIG. 7 is a sectional view schematically illustrating a semiconductor device in the middle of a manufacturing method of the semiconductor device according to a fourth exemplary embodiment.

FIG. 8 is a sectional view schematically illustrating the semiconductor device in the middle of the manufacturing method of the semiconductor device according to the fourth exemplary embodiment.

FIG. 9 is a sectional view schematically illustrating the semiconductor device in the middle of the manufacturing method of the semiconductor device according to the fourth exemplary embodiment.

FIG. 10 is a diagram schematically illustrating a semiconductor device in the middle of a manufacturing method of the semiconductor device according to a fifth exemplary embodiment.

FIG. 11 is a sectional view schematically illustrating a semiconductor device according to a sixth exemplary embodiment.

### DETAILED DESCRIPTION

Embodiments provide a semiconductor device that may reduce switching loss and a manufacturing method thereof.

In general, according to one embodiment, a semiconductor device includes a SiC substrate having a first surface and a second surface, a plurality of p-type first SiC areas on the first surface of the SiC substrate, an n-type second SiC area between the first SiC areas and the second surface, a third SiC area having an n-type dopant (impurity) concentration higher than that of the second SiC area, on the second surface of the SiC substrate, a first electrode on the first surface and electrically connected to the first SiC areas, and a second electrode on the second surface and electrically connected to the third SiC area. When, in the second SiC area, an area between the first SiC areas and the second surface is set as a first area, and an area between a portion between adjacent first SiC areas and the second surface is set as a second area, a Z_{1/2} level (recombination center) density of the first area is higher than that of the second area.

Hereinafter, exemplary embodiments are described with reference to the drawings. In addition, in the descriptions, the same members are denoted by the same reference numerals and the descriptions of already described members will be appropriately omitted.

In addition, in the description, the descriptions of n⁺, n, and n⁻ and p⁺, p and p⁻ represent relative of dopant concentration in respective conductivity types. That is, n⁺ represents a material in which the n-type dopant concentration is higher than n, and n⁻ represents a material in which the n-type dopant concentration is lower than n. In addition, p⁺ represents a material in which the p-type dopant concentration is higher than p, and p⁻ represents a material in which the p-type dopant concentration is lower than p. In addition, an n⁺ type and an n⁻ type may be simply referred to as an n type, and a p⁺ type, and p− type may be simply referred to as a p type.

The dopant concentration may be measured by, for example, secondary ion mass spectrometry (SIMS). In addition, the relative dopant concentration may be determined from, for example, a carrier concentration value obtained by scanning capacitance microscopy (SCM).

In the disclosure, the “SiC substrate includes a SiC layer formed by epitaxial growth on a substrate, for example.

### First Exemplary Embodiment

A semiconductor device according to a first exemplary embodiment includes a SiC substrate with a first surface and a second surface, a plurality of p-type first SiC areas provided on the first surface of the SiC substrate, an n-type second SiC area provided between the first SiC areas and the second surface, a third SiC area with an n-type dopant concentration higher than that of the second SiC area provided on the second surface of the SiC substrate, a first electrode provided on the first surface and electrically connected to the first SiC areas, and a second electrode provided on the second surface and electrically connected to the third SiC area. Considering the area between the first SiC areas and the second surface as a first area, and, an area between a portion between the adjacent first SiC areas and the second surface as a second area, the Z_{1/2} level density of the first area is higher than that of the second area.

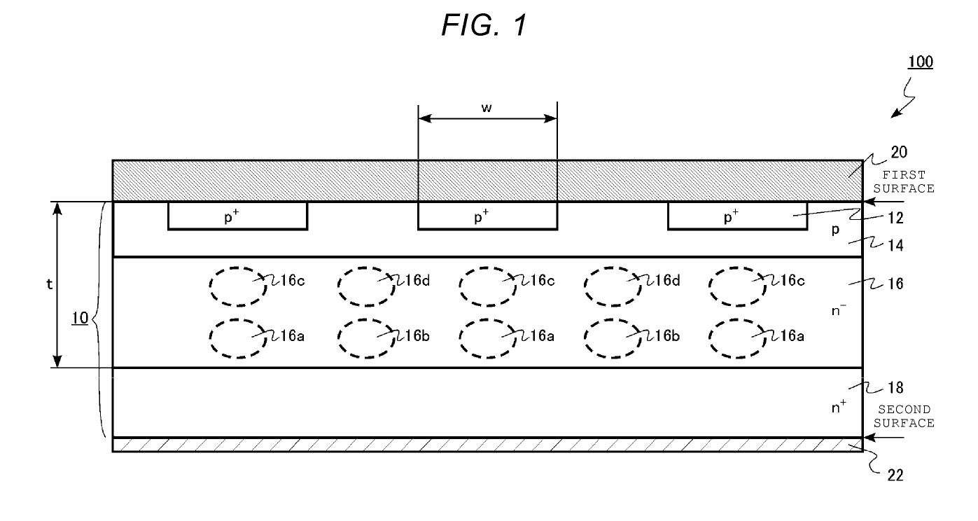

FIG. 1 is a sectional view schematically illustrating a semiconductor device according to the first exemplary embodiment. The semiconductor device according to the first exemplary embodiment is a PIN diode.

A PIN diode 100 includes a SiC substrate 10, a plurality of separate p⁺-type first anode areas (first SiC areas) 12 extending inwardly of, and terminating within, a p-type second anode area (fourth SiC area) 14, an n⁻-type drift area (second SiC area) 16, an n⁺-type cathode area (third SiC area) 18, an anode electrode (first electrode) 20, and a cathode electrode (second electrode) 22.

The SiC substrate 10 has a first surface and a second surface. In FIG. 1, the first surface is a surface on the upper side of the SiC substrate 10. In addition, in FIG. 1, the second surface is a surface on the lower side of the SiC substrate 10. The SiC substrate 10 is, for example, a SiC having a 4H-SiC structure.

The plural p⁺-type first anode areas (first SiC areas) 12 extend inwardly of the first surface of the SiC substrate 10. The p⁺-type first anode areas (first SiC areas) 12 are provided in the p-type second anode area 14.

With the p⁺-type first anode areas 12 being provided in the p-type second anode area 14 as a plurality of separate p⁺-type first anode areas 12, the quantity of holes injected into the n layer when the PIN diode 100 is turned on is reduced. As a result, the time (reverse recovery time) required to discharge the minority carriers when the diode is turned off is reduced, and the switching losses are decreased.

As illustrated in FIG. 1, the width (“w” in FIG. 1) of each of the p⁺-type first anode areas 12 is preferably twice as large or more than the distance (“t” in FIG. 1) from the first surface to the n⁺-type cathode area (third SiC area) 18. With this construct, the carbon hole concentration is easily non-uniformly distributed in the n⁻-type drift area 16 along the horizontal direction thereof in FIG. 1.

The p⁺-type first anode areas 12 contain p-type dopants. The p-type dopant is, for example, aluminum (Al). The concentration of the p-type dopant is, for example, in the range from 1×10¹⁹ cm⁻³ or more to 1×10²⁰ cm⁻³ or less.

The p-type second anode area (fourth SiC area) 14 is provided between the p⁺-type first anode areas 12 and the n⁻-type drift area (second SiC area) 16. The p-type second anode area 14 contains a p-type dopant. The p-type dopant is, for example, aluminum (Al). The dopant concentration in the p-type second anode area 14 is lower than that of the p⁺-type first anode areas 12. The dopant concentration of the p-type dopant is, for example, in the range from 5×10¹⁶ cm⁻³ or more to 5×10¹⁸ cm⁻³ or less.

The p-type second anode area 14 suppresses the extension of a depletion layer to the p⁺-type first anode areas 12 having high defect density when the PIN diode 100 is turned off which would increase the breakdown voltage value of the device.

The n⁻-type drift area (second SiC area) 16 is provided between the p⁺-type first anode areas 12 and the p-type second anode area 14, and the second surface

The n⁻-type drift area 16 contains n-type dopants. The n-type dopants are, for example, nitrogen (N). The dopant concentration of the n-type dopants is, for example, in the range from 1×10¹⁴ cm⁻³ or more to 5×10¹⁶ cm⁻³ or less. The thickness of the n⁻-type drift area 16 is, for example, in the range from 5 μm or more to 100 μm or less.

The n⁺-type cathode area (third SiC area) 18 is provided at and extends inwardly of the second surface of the SiC substrate 10. The n⁺-type cathode area 18 contains n-type dopants. The n-type dopant is, for example, nitrogen (N). The dopant concentration in the n⁺-type cathode area 18 is higher than that of the n⁻-type drift area 16. The dopant concentration of the n-type dopants is, for example, in the range from 1×10¹⁸ cm³ or more to 1×10²¹ cm⁻³ or less. The thickness of the n⁺-type cathode area 18 is, for example, in the range from 50 μm or more to 500 μm or less.

In addition, an n-type buffer layer (not illustrated) having an n-type dopant concentration having a value between the dopant concentration of the n⁺-type cathode area 18 and that of the n⁻-type drift area 16 may be provided between the n⁺-type cathode area 18 and the n⁻-type drift area 16. In addition, an n⁺ area having a dopant concentration greater than that of the n⁺-type cathode area 18 may be provided between the n⁺-type cathode area 18 and the cathode electrode (second electrode) 22.

The anode electrode (first electrode) 20 is provided on the first surface of the SiC substrate 10. The anode electrode 20 is electrically connected to the p⁺-type first anode areas 12. The anode electrode 20 is, for example, metal. The anode electrode 20 is, for example, a stacked film of titanium (Ti) and aluminum (Al).

A silicide layer may be provided in a portion of the anode electrode 20 that contacts the p⁺-type first anode areas 12. The silicide layer is, for example, nickel silicide. The contact between the anode electrode 20 and the p⁺-type first anode areas 12 is an ohmic contact.

The cathode electrode (second electrode) 22 is provided on the second surface of the SiC substrate 10. The cathode electrode 22 is electrically connected to the n⁺-type cathode area 18. The cathode electrode 22 is, for example, metal. The cathode electrode 22 is, for example, a stacked film of titanium (Ti) and nickel (Ni).

A silicide layer may be provided in the portion of the cathode electrode 22 that comes into contact with the n⁺-type cathode area 18. The silicide layer is, for example, nickel silicide. The contact between the cathode electrode 22 and the n⁺-type cathode area 18 is an ohmic contact.

In the PIN diode 100, the carbon hole concentration in the n⁻-type drift area 16 is non-uniformly distributed in the horizontal direction of FIG. 1. The carbon hole concentration directly corresponds with the Z_{1/2} level density as measured by the deep level transient spectroscopy (DLTS), i.e., a higher carbon hole concentration corresponds to a greater Z_{1/2} level density, and vice versa.

The n⁻-type drift area 16 includes, in the portion thereof between the individual discrete p⁺-type first anode areas 12 and the second surface, first areas 16a. The first areas 16a are located directly under the p⁺-type first anode area 12 and on the side of the n⁻-type drift area 16 closer to the n⁺-type cathode area 18 than to the p-type second anode area 14. Specifically, the first areas 16a are closer to the n⁺-type cathode area 18 than to an intermediate position of the n⁻-type drift area 16 in the thickness direction.

In addition, in the n⁻-type drift area 16, second areas 16b are present between the adjacent p⁺-type first anode areas 12 and the second surface. The second areas 16b are located between adjacent first areas 16a and at the same depth in the n-type drift area 16 under regions of the p-type second anode area 14 where the p⁺-type first anode areas 12 do not exist, and are closer to the n⁺-type cathode area 18 in the n⁻-type drift area 16 than to the p-type second anode layer 14. Specifically, the second areas 16b are areas which are closer to the n⁺-type cathode area 18 than to an intermediate position of the n⁻-type drift area 16 in the thickness direction.

Further, third areas 16c are present in the n⁻-type drift area 16 between the first areas 16a and the p-type second anode 14. The third areas 16c are areas in the n⁻-type drift area 16 which are directly under the p⁺-type first anode areas 12 and close to the p-type second anode area 14. Specifically, the third areas 16c are areas which are closer to the p-type second anode area 14 than to the intermediate position of the n⁻-type drift area 16 in the thickness direction, and thus are located between the first areas 16a and the p-type second anode area 14.

Also, in the n⁻-type drift area 16, areas between the second areas 16b and the first surface are fourth areas 16d. The fourth areas 16d are on the first surface side of the n⁻-type drift area 16 and directly under areas of the p-type second anode area 14 in which the p⁺-type first anode areas 12 do not exist. The fourth areas 16d are located in the n⁻-type drift area 16 closer to the p-type second anode area 14 than to the n⁺ third anode area 18 at the same depth inwardly of the n-type drift area 16 as the third areas 16c. Specifically, fourth areas 16d are areas which are closer to the p-type second anode area 14 than to the intermediate position of the n⁻-type drift area 16 in the thickness direction.

The carbon hole concentration of the first area 16a is higher than the carbon hole concentration of the second area 16b. That is, the Z_{1/2} level density of the first areas 16a is higher than that of the second areas 16b.

In addition, the carbon hole concentration of the first areas 16a is higher than that of the third areas 16c. That is, the Z_{1/2} level density of the first areas 16a is higher than that of the third areas 16c.

In addition, the carbon hole concentration of the second areas 16b is higher than that of the fourth areas 16d. That is, the Z_{1/2} level density of the second areas 16b is higher than that of the fourth areas 16d.

As described above, in the PIN diode 100, the areas located directly under the p⁺-type first anode areas 12, and particularly the areas close to the n⁺-type cathode area 18 have a higher carbon hole concentration. Also, the areas directly under the areas where the p⁺-type first anode areas do not exist have lower carbon hole concentration. Accordingly, in the PIN diode 100, the carbon hole concentration in the n⁻-type drift area 16 is non-uniformly distributed in the horizontal direction.

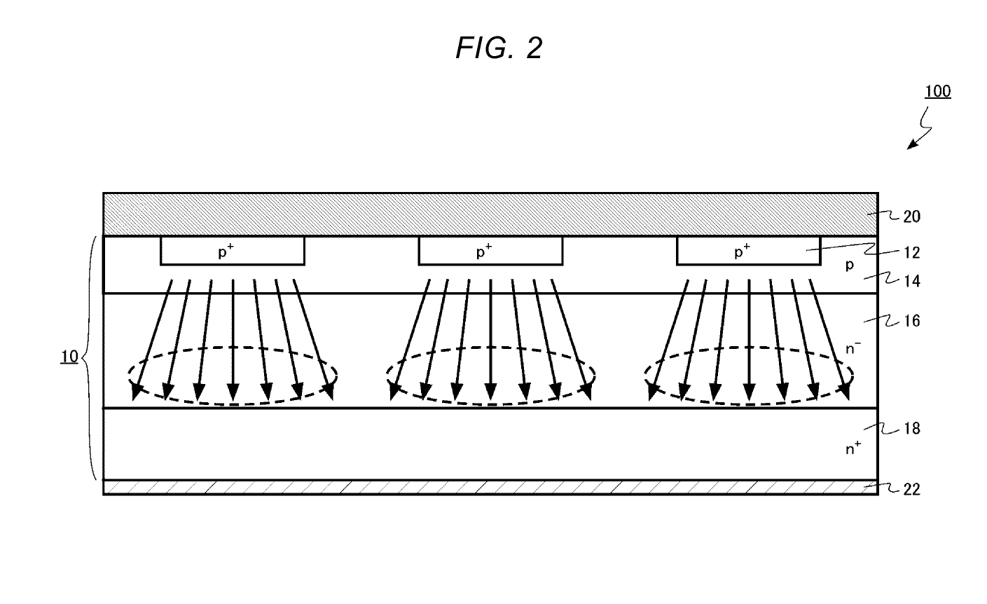

Subsequently, the functions and effects of the first exemplary embodiment are described. FIG. 2 is a diagram illustrating functions and effects of the first exemplary embodiment.

FIG. 2 is a diagram schematically illustrating the electric current distribution when the PIN diode 100 is turned on. The activation rate of p-type dopants in SiC is lower than, for example, that of p-type dopants in Si (silicon). Therefore, reducing the resistance of the p-type second anode area 14 is not easily accomplished.

Accordingly, the expansion of electric current in the horizontal direction when the PIN diode is turned on is suppressed, and thus the electric current density directly under the p⁺-type first anode areas 12 is increased. Therefore, the density of minority carriers (holes) remaining in the n⁻-type drift area 16 when the PIN diode is turned off becomes higher directly under the p⁺-type first anode areas 12.

In order to reduce the switching loss of the PIN diode 100, the minority carrier lifetime of the n⁻-type drift area 16 directly under the p⁺-type first anode areas 12 is preferably reduced. Particularly, when holes are extracted to the anode electrode 20 side, the minority carrier lifetime near the n⁺-type cathode area 18 from which the distance to the anode electrode 20 is long is preferably reduced.

The PIN diode 100 according to the first exemplary embodiment has higher carbon hole concentration in the first areas 16a as compared to the carbon hole concentration in the second areas 16b. In addition, the carbon hole concentration of the first areas 16a is higher than that of the third areas 16c.

The carbon holes function as killers of the minority carriers. Accordingly, the minority carrier lifetime of the areas in which the density of the injected minority carriers (holes) is high is reduced, and the recovery time of the device is thus reduced. Accordingly, a PIN diode having reduces the switching loss is achieved.

In a bipolar device of the PIN diode 100, the reduction of the on-resistance and the reduction of the switching loss have a trade-off relationship. For example, if the lifetime of the minority carriers is increased, the conductivity modulation effect is improved and the on-resistance is reduced. However, when the lifetime of the minority carrier is increased, the time required (reverse recovery time) to discharge minority carriers when the PIN diode is turned off is lengthened and the switching loss is increased. In addition, for example, if the injected quantity of the minority carriers increases, the conductivity modulation effect is improved, and the on-resistance is reduced. However, if the injection amount of the minority carriers is increased, the time required (reverse recovery time) for discharging the minority carriers when the PIN diode is turned off is increased, and the switching loss increases. Accordingly, a device design that enhances the trade-off relationship between the reduction of the on-resistance and the reduction of the switching loss is needed.

In the PIN diode 100, the carbon holes are non-uniformly distributed in the n⁻-type drift area 16 in the horizontal direction of FIG. 1, so that the density of the minority carriers (holes) remaining in the n⁻-type drift area 16 when the PIN diode is turned off becomes uniform. In a state in which the density of the remaining minority carriers (holes) is uniform, it becomes possible to improve the trade-off relationship between the reduction of the on-resistance and the reduction of the switching loss, for example, by optimizing the injected quantity of the minority carriers.

In addition, if the density of minority carriers (holes) remaining in the n⁻-type drift area 16 when the PIN diode is turned off is uniform across the layer, the in-plane distribution, i.e., differences in the reverse recovery current at different locations, of the reverse recovery current when the PIN diode is turned off is reduced. Therefore, the destruction of a device or the generation of noises by oscillation (ringing) caused by the reverse recovery current is suppressed.

Employing the structure of the PIN diode 100 according to the first exemplary embodiment, the switching loss of a PIN diode may be reduced. In addition, the trade-off relationship between the reduction of the on-resistance and the reduction of the switching loss may be enhanced. Further, the destruction of the device and the generation of noise by the oscillation (ringing) caused by the reverse recovery current may be suppressed.

### Second Exemplary Embodiment

A method of manufacturing a semiconductor device according to a second exemplary embodiment includes performing first ion implantation of p-type dopants for forming plural p-type SiC areas on a first surface of an n-type SiC substrate having the first surface and a second surface, performing second ion implantation for implanting carbon (C) on the SiC substrate from the first surface side, performing a heat treatment for diffusing carbon after the first ion implantation, forming a first electrode on the first surface of the SiC substrate, and forming a second electrode on the second surface of the SiC substrate.

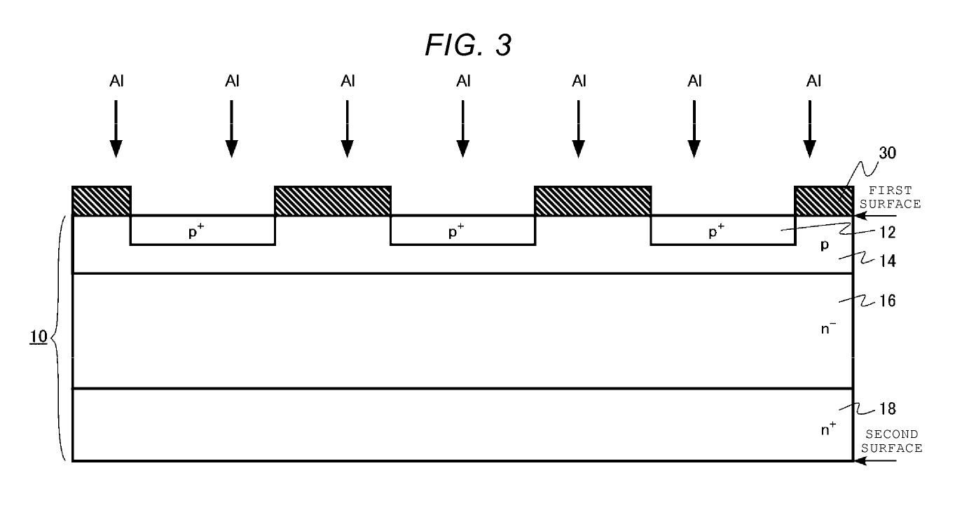

The method of manufacturing the semiconductor device according to the second exemplary embodiment is an example of the method of manufacturing the PIN diode 100 according to the first exemplary embodiment. FIGS. 3 to 5 are sectional views schematically illustrating the semiconductor device in intermediate steps of the manufacturing method of the semiconductor device according to the second exemplary embodiment.

First, the n-type SiC substrate 10 which has the first surface and the second surface is prepared. The SiC substrate 10 includes the n⁻-type drift area 16 on the n⁺-type cathode area 18. The n⁻-type drift area 16 is an epitaxial layer formed, for example, by epitaxial growth of an n⁻-type layer on the n⁺-type cathode area 18.

Subsequently, p-type dopants are ion implanted into the first surface, and the p-type second anode area 14 is thus formed. The p-type dopants are, for example, aluminum (Al).

Subsequently, a mask material 30 as shown in FIG. 3 is formed on the first surface. The mask material 30 is, for example, a silicon oxide film formed by a chemical vapor deposition (CVD) method.

Subsequently, the mask material 30 is patterned. The mask material 30 is patterned, for example, by a photolithography method and a reactive ion etching (RIE) method.

Subsequently, ion implantation (first ion implantation) of the p-type dopants is performed while using the mask material 30 to mask portions of the p-type second anode area 14 (FIG. 3). The plural p⁺-type first anode areas (SiC areas) 12 are thus formed in the second anode area 14 by the first ion implantation. The p-type dopants are, for example, aluminum (Al).

Subsequently, the mask material 30 is removed. The mask material 30 is removed, for example, by wet etching.

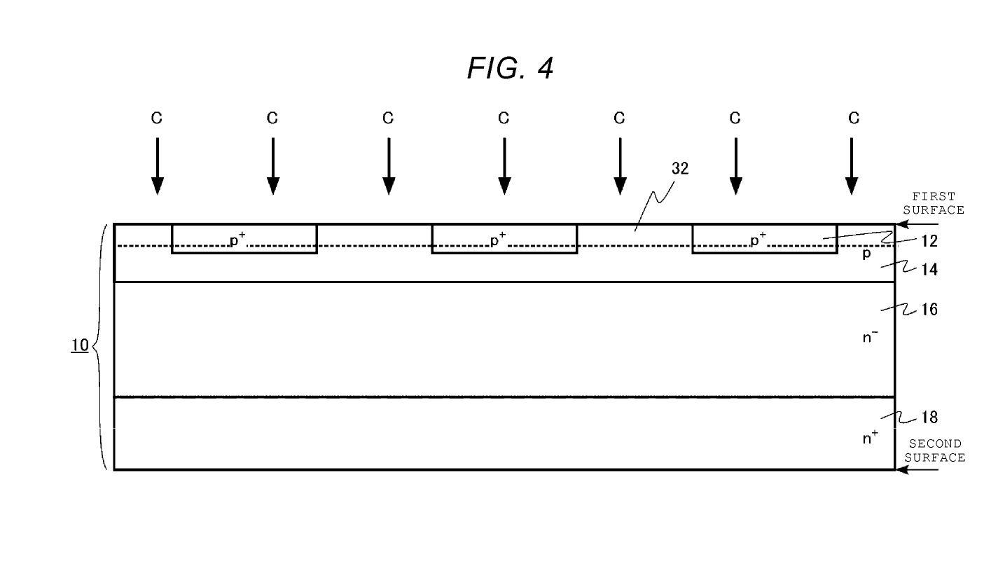

Subsequently, a second ion implantation step for implanting carbon (C) into the p type layer 14 from the first surface side of the substrate is performed (FIG. 4). A carbon implantation layer 32 is formed by the second ion implantation step. Carbon is implanted in the p⁺-type first anode areas 12 by the second ion implantation.

In addition, the second ion implantation may be performed before the first ion implantation.

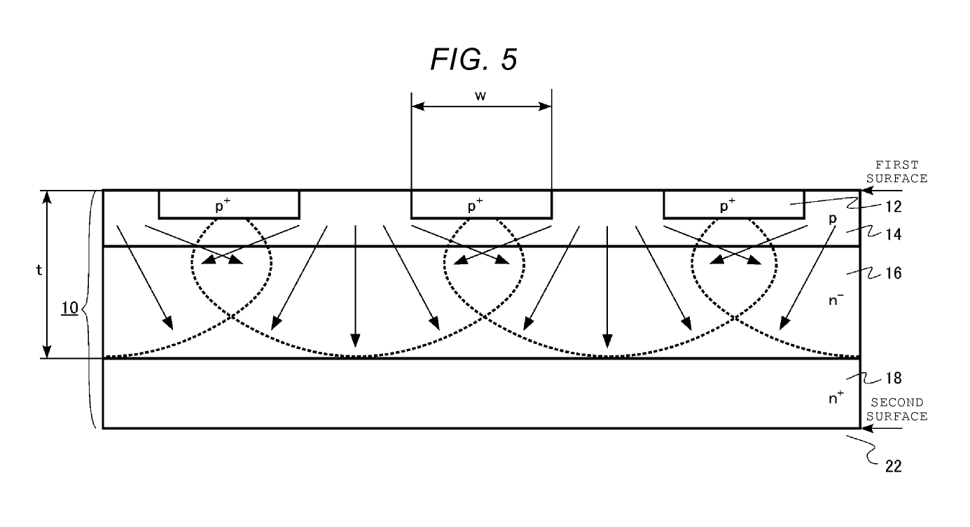

Next, a heat treatment is performed to diffuse the carbon implanted into the p-type second anode area 14 (FIG. 5). Carbon in the carbon implantation layer 32 is diffused by the heat treatment (arrow in FIG. 5). At this point, carbon is trapped in defects in the p⁺-type first anode areas 12. Particularly, if aluminum of which an atomic radius is great is used as the p-type dopants, the majority of the carbon implanted into the p⁺-type first anode areas 12 remains trapped in the p⁺-type first anode areas 12.

Accordingly, as indicated with broken lines in FIG. 5, the diffusion of carbon from the p⁺-type first anode areas 12 is suppressed. Therefore, the carbon concentration of the n⁻-type drift area 16 directly below the p⁺-type first anode areas 12 is lower than the carbon concentration of the n⁻-type drift area 16 directly under the areas between the p⁺-type first anode areas 12.

The heat treatment to diffuse carbon is performed, for example, in the temperature in the range from 1,300° C. or higher to 2,000° C. or lower in a non-oxidizing atmosphere. The p-type dopants in the p⁺-type first anode areas 12 are also activated by the heat treatment. In addition, the heat treatment for activating the p-type dopants in the p⁺-type first anode areas 12 may be separately performed.

Directly under the areas between the p⁺-type first anode areas 12, the conditions of the second ion implantation and the conditions of the heat treatment are preferably set so that carbon in the implanted carbon implantation layer 32 reaches as far as the n⁺-type cathode area 18 after the heat treatment is completed.

The width (“w” in FIG. 5) of the p⁺-type first anode area 12 is preferably twice or more as large as the distance (“t” in FIG. 5) from the first surface to the n⁺-type cathode area 18. If the width is set to this condition, in portions of the n⁻-type drift area 16 directly under the areas between the p⁺-type first anode areas 12, even if carbon reaches the n⁺-type cathode area 18, little carbon reaches portions directly under the p⁺-type first anode areas 12, and the carbon concentration is non-uniformly distributed in the n⁻-type drift area 16 in the horizontal direction.

Thereafter, according to the well-known processes, the anode electrode (first electrode) 20 and the cathode electrode (second electrode) 22 are formed. According to the manufacturing method described above, the PIN diode 100 is manufactured.

According to the manufacturing method according to the second exemplary embodiment, the carbon concentration of the n⁻-type drift area 16 directly below the p⁺-type first anode areas 12 is lower than that of the n⁻-type drift area 16 directly under the areas between the p⁺-type first anode areas 12. Accordingly, the carbon hole concentration of the areas directly under the p⁺-type first anode areas 12, particularly, the areas close to the n⁺-type cathode area 18, is increased. Further, the carbon hole concentration of the areas directly under the areas in which the p⁺-type first anode areas 12 do not exist is reduced.

Accordingly, according to the manufacturing method according to the second exemplary embodiment, the PIN diode 100 in which the switching loss may be reduced may be manufactured. According to the second exemplary embodiment, at the time of carbon ion implantation (second ion implantation), areas in which the p⁺-type first anode areas 12 or the p⁺-type first anode areas 12 are expected to be formed are not masked. In addition, the activation of the p⁺-type first anode areas 12 and the carbon diffusion step are performed by the same heat treatment. Accordingly, the PIN diode 100 may be manufactured by a simple manufacturing method.

### THIRD EXEMPLARY EMBODIMENT

A method of manufacturing a semiconductor device according to a third exemplary embodiment is the same as that according to the second exemplary embodiment except for not performing the ion implantation in the p-type SiC area when the second ion implantation for implanting carbon (C) is performed from the first surface side. Accordingly, the descriptions of the contents which are the same as in the second exemplary embodiment are partially omitted.

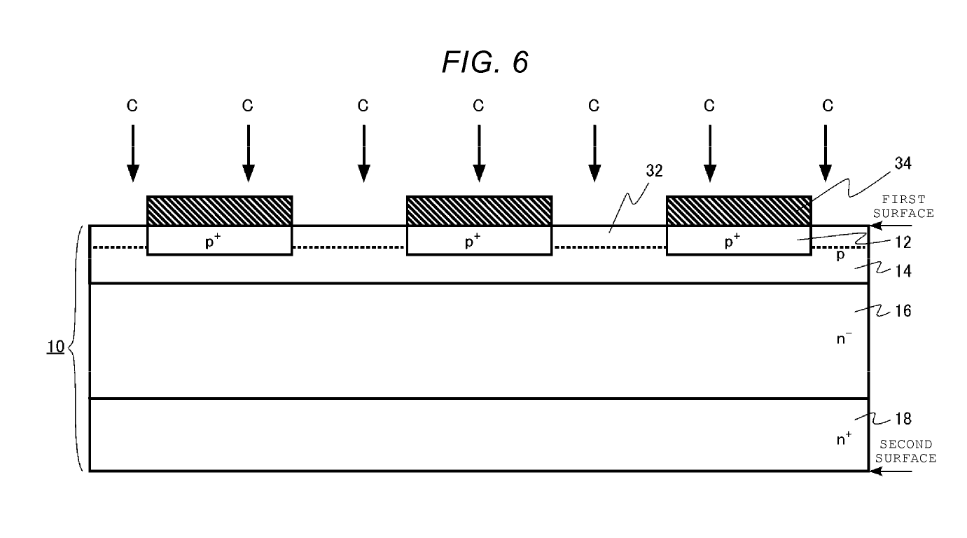

The method of manufacturing the semiconductor device according to the third exemplary embodiment is an example of the method of manufacturing the PIN diode 100 according to the first exemplary embodiment. FIG. 6 is a sectional view schematically illustrating the semiconductor device in the middle of the manufacturing method of the semiconductor device according to the third exemplary embodiment.

When the second ion implantation for implanting carbon (C) from the first surface side is performed, masking is performed with a mask material 34 (FIG. 6). The p⁺-type first anode areas (SiC areas) 12 are covered with the mask material 34. Accordingly, the carbon implantation layer 32 is formed in areas other than the p⁺-type first anode areas 12.

When the heat treatment for diffusing carbon is performed, since carbon is not implanted in the p⁺-type first anode areas 12, the carbon concentration of the n⁻-type drift area 16 directly under the p⁺-type first anode areas 12 will be lower than that in the second exemplary embodiment. In other words, the carbon hole concentration of the n⁻-type drift area 16 directly under the p⁺-type first anode areas 12 will be higher than that in the second exemplary embodiment. Accordingly, the PIN diode 100 in which switching loss is further reduced may be manufactured.

### Fourth Exemplary Embodiment

A method of manufacturing the semiconductor device according to the fourth exemplary embodiment includes performing first ion implantation for implanting carbon (C) in a select area of a first surface of an n-type SiC substrate having the first surface and a second surface, performing a first heat treatment of diffusing carbon after the first ion implantation, performing second ion implantation of p-type dopants for forming a p-type SiC area in an area other than the select area, performing a second heat treatment for activating the p-type dopants after the second ion implantation, forming a first electrode on the first surface of the SiC substrate, and forming a second electrode on the second surface of the SiC substrate.

The fourth exemplary embodiment is different from the second or third exemplary embodiment in that the heat treatment for diffusing carbon is performed before the p-type SiC area is formed. The descriptions of the contents which are the same as in the second or third exemplary embodiment are partially omitted.

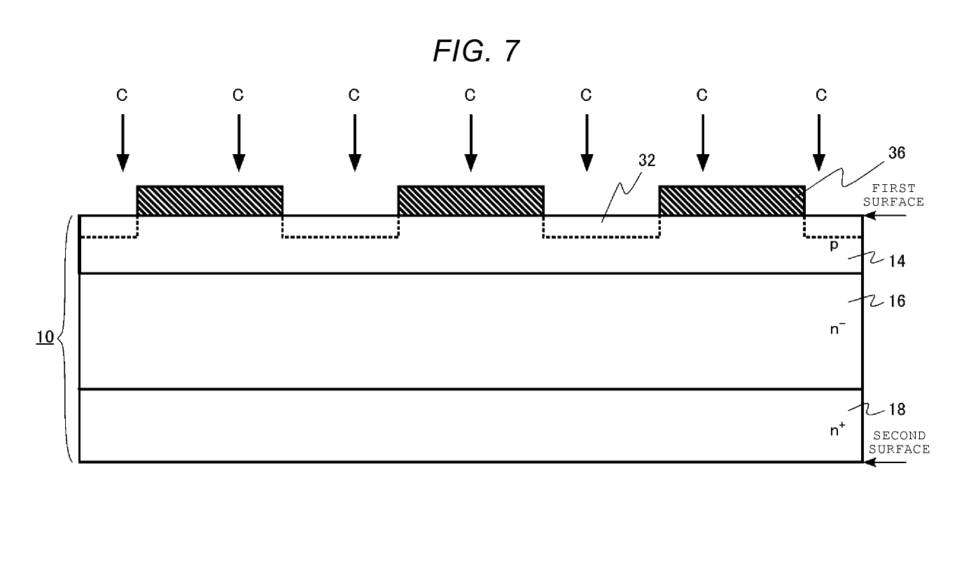

FIGS. 7 to 9 are sectional views schematically illustrating the semiconductor device in the middle of the manufacturing method of the semiconductor device according to the fourth exemplary embodiment.

Initially, the n-type SiC substrate 10 having the first surface and the second surface is prepared. The SiC substrate 10 includes the n⁻-type drift area 16 on the n⁺-type cathode area 18.

Subsequently, the ion implantation of p-type dopants is performed on the first surface, and the p-type second anode area 14 is formed. The p-type dopants are, for example, aluminum (Al).

Subsequently, a mask material 36 is formed on the first surface. The mask material 36 is, for example, a silicon oxide film formed by a chemical vapor deposition (CVD) method.

Subsequently, the mask material 36 is patterned. The patterning of the mask material 36 is performed, for example, by a photolithography method and an RIE method.

Subsequently, the first ion implantation for implanting carbon (C) is performed in a select area from the first surface side using the mask material 36 as a mask (FIG. 7). The carbon implantation layer 32 is formed by the first ion implantation.

Subsequently, the mask material 36 is removed. The mask material 36 is removed, for example, by wet etching.

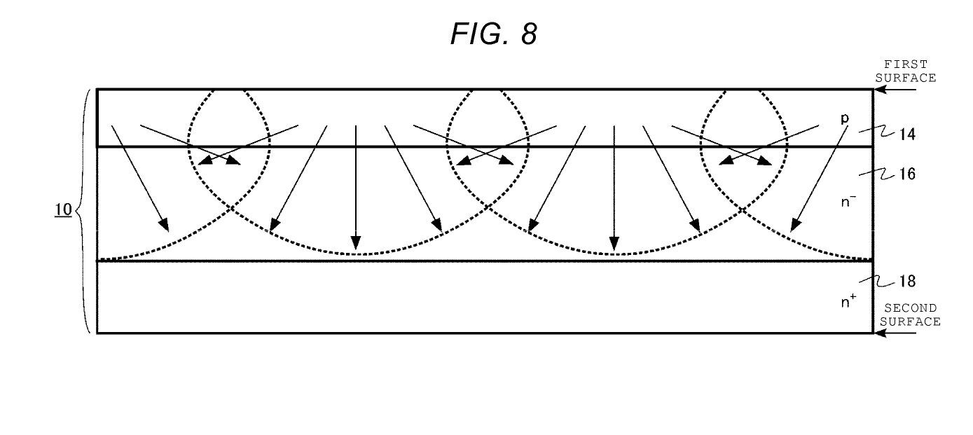

Subsequently, the first heat treatment for diffusing carbon is performed. Carbon in the carbon implantation layer 32 is diffused by the first heat treatment (FIG. 8). The first heat treatment is performed, for example, in the temperature in the range from 1,100° C. or higher to 1,400° C. or lower in the non-oxidizing atmosphere.

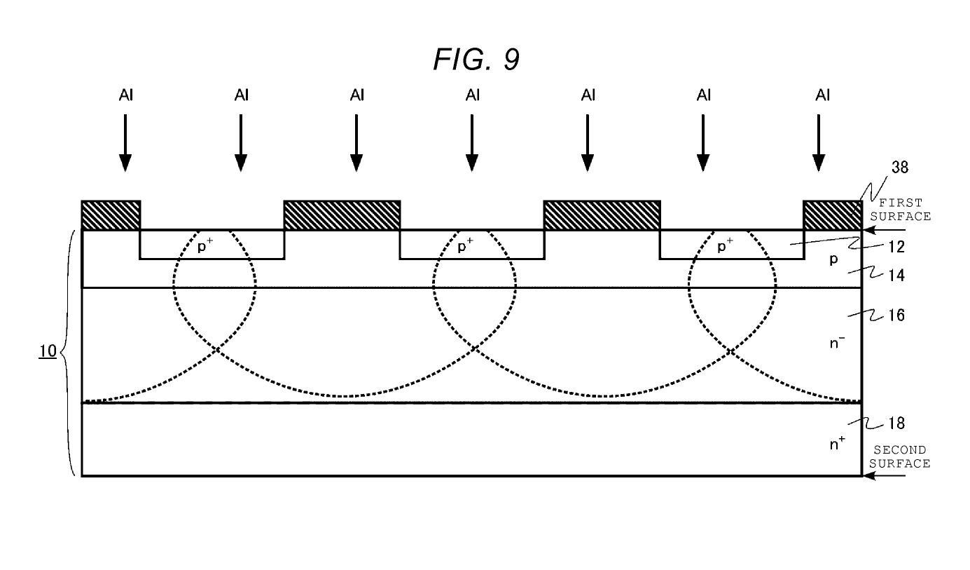

Subsequently, a mask material 38 is formed on the first surface. Next, the mask material 38 is patterned. Next, the p-type dopant ion implantation (second ion implantation) is performed using the mask material 38 as a mask (FIG. 9). The p-type dopant is, for example, aluminum (Al).

The plural p⁺-type first anode areas (SiC areas) 12 are formed by the second ion implantation. The p⁺-type first anode areas (SiC areas) 12 are formed by the second ion implantation in the open areas extending through the mask layer 36 after the patterning of the mask layer 36.

Subsequently, the mask layer 36 is removed. Next, the second heat treatment for activating p-type dopants is performed. The second heat treatment is performed, for example, in the temperature in the range from 1,800° C. or higher to 2,000° C. or lower in the non-oxidizing atmosphere. The second heat treatment is preferably performed at a higher temperature than the first heat treatment.

Thereafter, according to the well-known processes, the anode electrode (first electrode) 20 and the cathode electrode (second electrode) 22 are formed. According to the manufacturing methods described above, the PIN diode 100 is manufactured.

The PIN diode 100 in which the switching loss is reduced may be manufactured by the manufacturing method according to the fourth exemplary embodiment. In addition, according to the fourth exemplary embodiment, the condition of the first heat treatment for diffusing carbon may be performed in a manner independent of the conditions for forming the p⁺-type first anode areas 12. Accordingly, the degree of freedom of the manufacturing process is expanded.

### Fifth Exemplary Embodiment

A method of manufacturing a semiconductor device according to a fifth exemplary embodiment includes performing ion implantation of p-type dopants for forming a p-type SiC area on a first surface of an n-type SiC substrate having the first surface and a second surface, forming a thermal oxide film on the first surface after the ion implantation, removing the thermal oxide film, forming a first electrode on the first surface of the SiC substrate, and forming a second electrode on the second surface of the SiC substrate.

The fifth exemplary embodiment is different from the second to fourth exemplary embodiments in that carbon generated in the SiC substrate by thermal oxidation is diffused. The descriptions of the contents which are the same as in the second to fourth exemplary embodiments are partially omitted.

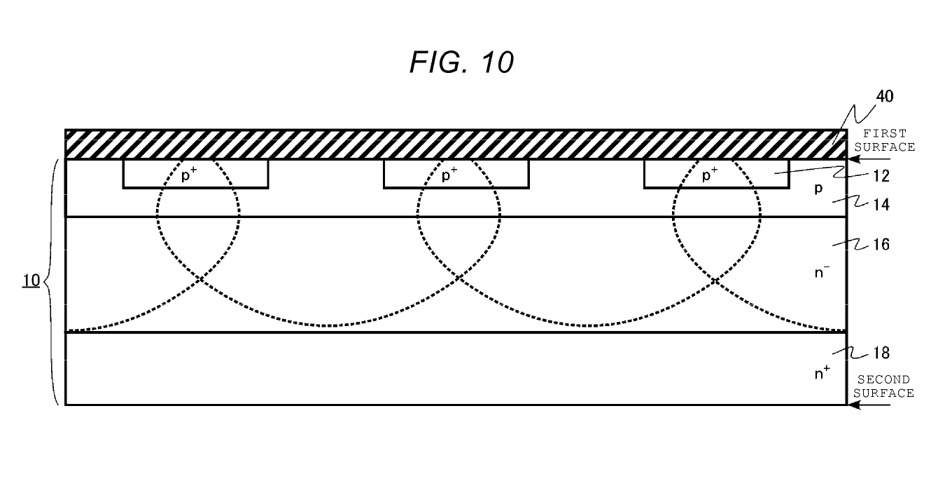

FIG. 10 is a diagram schematically illustrating the semiconductor device in the middle of the manufacturing method of the semiconductor device according to the fifth exemplary embodiment.

Until the ion implantation of p-type dopants is performed on the first surface and the plural p-type first anode areas 12 are formed, the processes are the same as in the second exemplary embodiment.

Subsequently, a heat treatment for activating p-type dopants is performed. The heat treatment is performed, for example, at a temperature in the range from 1,800° C. or higher to 2,000° C. or lower in a non-oxidizing atmosphere.

Subsequently, a thermal oxide film 40 is formed on the first surface. When the thermal oxide film 40 is formed, surplus carbon is generated adjacent the interface of the SiC substrate 10 and the thermal oxide film 40. This carbon is diffused into the SiC substrate 10.

At this point, carbon is trapped by defects in the p⁺-type first anode areas 12. Accordingly, as indicated in FIG. 10 with broken lines, the diffusion of carbon in the p⁺-type first anode areas 12 is suppressed.

The thermal oxide film 40 is formed, for example, by locating the substrate 10 in an oxidizing atmosphere for 30 minutes or longer to 6 hours or shorter at a temperature in the range from 1,100° C. or higher to 1,300° C. or lower.

Thereafter, the thermal oxide film 40 is removed. The removal of the thermal oxide film 40 is performed, for example, by wet etching.

Thereafter, by well-known processes, the anode electrode (first electrode) 20 and the cathode electrode (second electrode) 22 are formed. According to the manufacturing method, the PIN diode 100 is manufactured.

Owing to the manufacturing method according to the fifth exemplary embodiment, the PIN diode 100 in which the switching loss may be reduced may be manufactured.

### Sixth Exemplary Embodiment

A semiconductor device according to a sixth exemplary embodiment includes a SiC substrate having a first surface and a second surface, plural p-type first SiC areas provided on the first surface of the SiC substrate, an n-type second SiC area provided between the first SiC areas and the second surface, a third SiC area having higher n-type dopant concentration than that in a second SiC area provided on the second surface of the SiC substrate, a first electrode provided on the first surface side of the SiC substrate and electrically connected to the first SiC areas, and a second electrode provided on the second surface side of the SiC substrate and electrically connected to the third SiC area, in which when, in the second SiC area, an area between the first SiC areas and the second surface is set as a first area, and, in the second SiC area, an area between a portion between the adjacent first SiC areas and the second surface is set as a second area, the Z_{1/2} level density of the first area is higher than that of the second area.

The semiconductor device according to the sixth exemplary embodiment further includes a fourth SiC area that is provided between the first SiC areas and the second SiC area, and that has lower p-type dopant concentration than that of the first SiC areas, an n-type fifth SiC area provided on the first surface in the fourth SiC area, a gate insulating film provided on the fourth SiC area, and a gate electrode provided to interpose a gate insulating film between portions of the fourth SiC area.

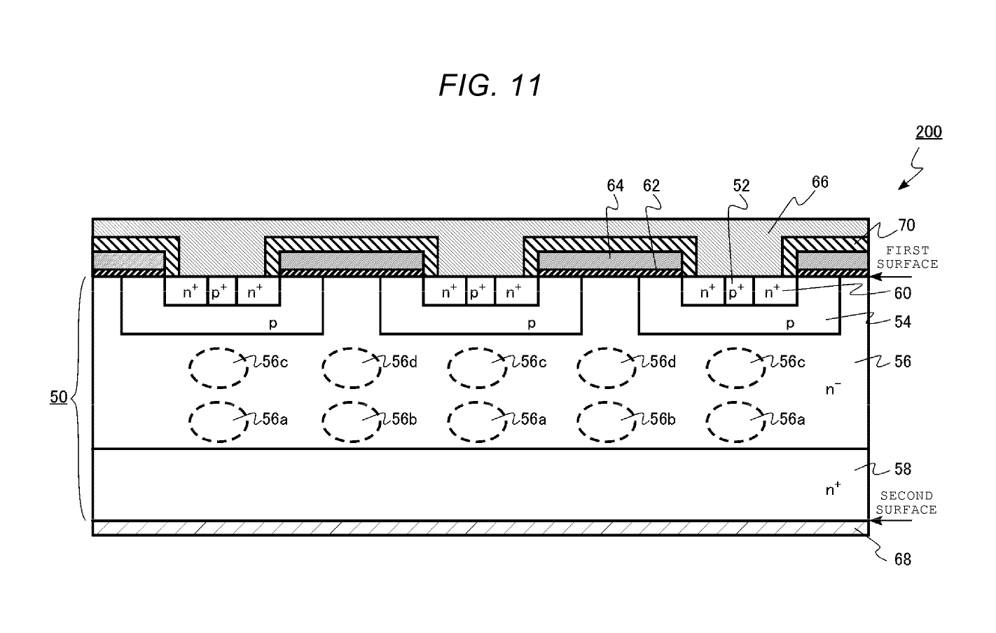

FIG. 11 is a sectional view schematically illustrating the semiconductor device according to the sixth exemplary embodiment. The semiconductor device according to the sixth exemplary embodiment is metal semiconductor field effect transistor (MOSFET).

A MOSFET 200 includes a SiC substrate 50, p⁺-type contact areas (first SiC areas) 52, p-type base areas (fourth SiC areas) 54, an n⁻-type drift area (second SiC area) 56, an n⁺-type drain area (third SiC area) 58, n⁺-type source areas (fifth SiC areas) 60, gate insulating films 62, gate electrodes 64, a source electrode (first electrode) 66, a drain electrode (second electrode) 68, and interlayer insulating films 70.

In the MOSFET 200, the p⁺-type contact areas (first SiC areas) 52, the p-type base areas (fourth SiC areas) 54, the n⁻-type drift area (second SiC area) 56, and the n⁺-type drain area (third SiC area) 58 form a body diode. The body diode is a PIN diode.

In the MOSFET 200, the carbon hole concentration in the n⁻-type drift area 56 is distributed in the horizontal direction.

In the n⁻-type drift area 56, areas between the p⁺-type contact areas 52 and the second surface are set as first areas 56a. The first areas 56a are areas in the n⁻-type drift area 56 directly under the p⁺-type contact areas 52 and close to the n⁺-type drain area 58. Specifically, the first areas 56a are areas which are closer to the n⁺-type drain area 58 than to the intermediate position of the n⁻-type drift area 56 in the thickness direction.

In addition, in the n⁻-type drift area 56, areas between portions between adjacent p⁺-type contact areas 52 and the second surface are set as second areas 56b. The second areas 56b are directly under the areas in which the p⁺-type contact areas 52 do not exist on the first surface, and are close to the n⁺-type drain area 58 in the n⁻-type drift area 56. Specifically, the second areas 56b are areas which are closer to the n⁺-type drain area 58 than to an intermediate position of the n⁻-type drift area 56 in the thickness direction.

Further, in the n⁻-type drift area 56, areas between the first areas 56a and the first surface are set as third areas 56c. The third areas 56c are located in the n⁻-type drift area 56 directly under the p⁺-type contact areas 52 and close to p-type base areas 54. Specifically, the third areas 56c are areas which are closer to the p-type base areas 54 than to an intermediate position of the n⁻-type drift area 56 in the thickness direction.

Also, in the n⁻-type drift area 56, areas between the second areas 56b and the first surface are set as fourth areas 56d. The fourth areas 56d are located in the n⁻-type drift area directly under areas in which the p⁺-type contact areas 52 do not exist in the first surface, and close to the p-type base areas 54 in the n⁻-type drift area 56. Specifically, the fourth areas 56d are areas which are closer to the p-type base areas 54 than to the intermediate position of the n⁻-type drift area 56 in the thickness direction.

The carbon hole concentration of the first areas 56a is higher than that of the second areas 56b. That is, the Z_{1/2} level density of the first areas 56a is higher than that of the second areas 56b.

In addition, the carbon hole concentration of the first areas 56a is higher than that of the third areas 56c. That is, the Z_{1/2} level density of the first areas 56a is higher than that of the third areas 56c.

In addition, the carbon hole concentration of the second areas 56b is higher than that of the fourth areas 56d. That is, the Z_{1/2} level density of the second areas 56b is higher than that of the fourth areas 56d.

As described above, in the MOSFET 200, the carbon hole concentration in the areas directly under the p⁺-type contact areas 52, particularly, in the areas close to the n⁺-type drain area 58, is high. Also, the carbon hole concentration of the areas directly under areas in which the p⁺-type contact areas 52 do not exist is low. In the MOSFET 200, the carbon hole concentration is non-uniformly distributed in the n⁻-type drift area 56 in the horizontal direction. In the MOSFET 200, the minority carrier lifetime of the areas directly under the p⁺-type contact areas 52, particularly, the minority carrier lifetime of the areas close to the n⁺-type drain area 58 is short.

In the MOSFET 200 according to the sixth exemplary embodiment, the switching loss of the body diode which is a PIN diode is reduced by the same functions of the PIN diode 100 according to the first exemplary embodiment.

Accordingly, the MOSFET 200 in which the switching loss of the body diode is reduced may be achieved.

According to the first to sixth exemplary embodiments, a termination structure is not described, but a termination structure may be provided near element areas in order to achieve a high voltage resistant semiconductor device.

While certain exemplary embodiments have been described, these exemplary embodiments have been presented by way of example only, and are not intended to limit the scope of the inventions. Indeed, the novel exemplary embodiments described herein may be embodied in a variety of other forms; furthermore, various omissions, substitutions and changes in the form of the exemplary embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a SiC substrate having a first surface and a second surface;
a plurality of p-type first SiC areas on the first surface of the SiC substrate;
an n-type second SiC area between the first SiC areas and the second surface;
a third SiC area having an n-type dopant concentration higher than an n-type dopant concentration of the second SiC area, on the second surface of the SiC substrate;
a first electrode on the first surface and electrically connected to the first SiC areas; and
a second electrode on the second surface and electrically connected to the third SiC area,
wherein when, in the second SiC area, an area between the first SiC area and the second surface is set as a first area, and an area between a portion between adjacent first SiC areas and the second surface is set as a second area, a Z_{1/2} level density of the first area is higher than a Z_{1/2} level density of the second area.

2. The device according to claim 1, wherein the first area and the second area are located at the same depth inwardly of the first surface of the SiC substrate.

3. The device according to claim 1, wherein the Z_{1/2} level density of the first area is higher than the Z_{1/2} level density of a third area, which is between the first area and the first surface in the second SiC area.

4. The device according to claim 1, wherein a p-type dopant concentration of the first SiC area is greater than a p-type dopant concentration of a fourth SiC area, which is between the first SiC areas and the second SiC area.

5. The device according to claim 4, further comprising:
an n-type fifth SiC area provided on the fourth SiC area;
a gate insulating film on the fourth SiC area; and
a gate electrode located on the gate insulating film at a location over the fourth SIC area.

6. The device according to claim 4, further comprising a fifth SiC area located adjacent to, and contacting, the first SiC area, wherein the fifth SiC area is of an n-type having a greater n-type dopant concentration than an n-type dopant concentration of the second SIC area.

7. The device according to claim 1,
wherein a width of the first SiC area is twice or more as wide as the distance from the first surface to the third SiC area.

8. The device according to claim 1, wherein a carbon hole concentration in the n-type second SiC area increases in the direction from the first surface of the substrate toward the second surface of the substrate.

9. The device according to claim 8, wherein a carbon hole concentration in the n-type second SiC area in the first area is greater than a carbon hole concentration in the n-type second SiC area in the second area.

10. A method of manufacturing a semiconductor device, comprising:
performing a first ion implantation of p-type dopants to form a plurality of p-type SiC areas on a first surface of an n-type SiC substrate having a first surface and a second surface;
performing a second ion implantation to implant carbon (C) into the SiC substrate from the first surface side;
performing a heat treatment to diffuse carbon after the second ion implantation;
forming a first electrode on the first surface; and
forming a second electrode on the second surface.

11. The method according to claim 10, further comprising:
performing the second ion implantation after the first ion implantation.

12. The method according to claim 10,
wherein carbon is implanted in areas including the p-type SiC areas during the second ion implantation.

13. The method according to claim 10,
wherein the heat treatment to diffuse carbon after the first ion implantation is performed at a temperature of 1,800° C. or higher.

14. The method according to claim 10, wherein the second ion implantation is performed before the first ion implantation.

15. The method according to claim 14, further comprising:
performing a second heat treatment of the substrate after the first ion implantation is performed.

16. The method according to claim 10, further comprising:
providing the plurality of p-type SiC areas having a width sufficient to provide a lower implanted carbon concentration in the n-doped substrate in areas directly below the plurality of p-type SiC areas than in areas of the n-doped substrate between the plurality of p-type SiC areas.

17. A method of manufacturing a semiconductor device, comprising:
performing ion implantation of p-type dopants to form a p-type SiC area on a first surface of an n-type SiC substrate having the first surface and a second surface;
forming a thermal oxide film on the first surface after the ion implantation;
removing the thermal oxide film;
forming a first electrode on the first surface; and
forming a second electrode on the second surface.

18. The method according to claim 17,
wherein a temperature at which the thermal oxide film is formed is in the range from 1,100° C. or higher to 1,300° C. or lower.

19. The method according to claim 17, wherein a Z_{1/2} level density of an n-type SiC directly below the p-type SiC area on the first surface of the n-type SiC substrate is greater than a Z_{1/2} level density of an n-type SiC not directly below the p-type SiC area on the first surface of the n-type SiC substrate.

20. The method according to claim 17, wherein a Z_{1/2} level density of an n-type SiC directly below the p-type SiC area on the first surface of the n-type SiC substrate increases in the direction from the first surface to the second surface.
